(19) United States
(12) Patent Application Publication
(10) Pub. No.: US 2012/0181639 A1
(43) Pub. Date: Jul. 19, 2012

(54) COMPONENT AND METHOD FOR THE MANUFACTURE THEREOF

(76) Inventors: Ricardo Ehrenpfordt, Korntal-Muenchingen (DE); Ulrike Scholz, Korntal (DE)

(21) Appl. No.: 13/334,408

(22) Filed: Dec. 22, 2011

(30) Foreign Application Priority Data
Dec. 23, 2010 (DE) 102010064120.0

(51) Int. Cl. H01L 29/84; H01L 21/02

(52) U.S. Cl. 257/416; 438/51; 257/E29.324; 257/E21.002

(57) ABSTRACT

A cost-effective and space-saving component that includes a MEMS element and an access channel to the membrane structure of the MEMS element.

The MEMS element is mounted by the rear side of the component on a substrate and is at least partially embedded in a molding compound. An access port is formed in the molding compound. The component also includes at least one semiconductor component having at least one through hole that is integrated in the molding compound above the MEMS element at a distance from the membrane structure, so that a hollow space is located between the semiconductor component and the membrane structure. The access port in the molding compound opens into the through hole of the semiconductor component and, together with this and the hollow space between the further semiconductor component and the membrane structure, forms the access channel to the membrane structure.

A cost-effective and space-saving component that includes a MEMS element and an access channel to the membrane structure of the MEMS element. The MEMS element is mounted by the rear side of the component on a substrate and is at least partially embedded in a molding compound. An access port is formed in the molding compound. The component also includes at least one semiconductor component having at least one through hole that is integrated in the molding compound above the MEMS element at a distance from the membrane structure, so that a hollow space is located between the semiconductor component and the membrane structure. The access port in the molding compound opens through into the through hole of the semiconductor component and, together with this and the hollow space between the further semiconductor component and the membrane structure, forms the access channel to the membrane structure.

### CROSS-REFERENCE TO RELATED APPLICATIONS

The present application claims priority to Application No. 10 2010 064 120.0, filed in the Federal Republic of Germany on Dec. 23, 2010, which is expressly incorporated herein in its entirety by reference thereto.

### FIELD OF THE INVENTION

The present invention relates to a component, as well as to a method for the manufacture thereof. For example, the component includes at least one MEMS element having at least one membrane structure configured in the top side thereof. The MEMS element is mounted by the rear side thereof on a substrate. Moreover, the MEMS element is at least partially embedded in a molding compound in which at least one access port is formed.

### BACKGROUND INFORMATION

German Published Patent Application No. 199 29 026 describes using a molded housing for packaging an MEMS pressure sensor element. A sensor membrane, which spans a cavity in the rear side of the element, is configured in the top side of the pressure sensor element. The cavity is sealed pressure-tight with the aid of a socket substrate and is used as a reference volume for sensing pressure. This structure is mounted on a leadframe and electrically contacted. The thus populated leadframe substrate is then inserted into a molding tool and is embedded in a transfer molding process in a plastic molding material that forms the molded housing. To form a pressure access port in the molded housing, in addition to an upper part and a lower part, the injection tool includes a plunger to keep the sensor membrane free of the molding compound. To ensure that the sensitive membrane structure is not damaged, the plunger is not placed directly on the top side of the sensor element. Rather, it is kept at a small distance from the membrane surface. Through a special cooling of the plunger, the flowability of the molding compound is reduced in the vicinity thereof. It is intended to thereby prevent the molding compound from penetrating into the gap between the plunger and the sensor membrane and solidifying in the membrane region.

In practical applications, this method turns out to be problematic in several respects. In the first case, the process control is relatively expensive and error-prone since the cooling of the plunger must be adapted to the plunger geometry, to the gap width between the plunger and the sensor membrane, and to the viscosity properties of the molding compound. At any rate, in terms of process, it is not possible to reliably prevent molding compound from getting in underneath the plunger. Accordingly, the plunger cross section must be dimensioned to be larger than the membrane surface in order to prevent the mold flash, which forms when molding compound gets in underneath, from adversely affecting the function of the active sensor membrane. However, this requires a surface area allowance on the top side of the element that is otherwise not usable.

In conventional methods, a molding tool that can provide reliable sealing action when placed on the MEMS structure of a pressure sensor element is not known. Moreover, the membranes of MEMS elements, such as microphones, for example, are often designed to be considerably thinner and more fragile than those of pressure sensor elements. The MEMS structures in question are not performance-rated for the mechanical loads of the magnitude that occur when a molding tool is set down sealingly.

Finally, it is noted that the mold packaging described in German Published Patent Application No. 199 29 026 is designed for a side-by-side configuration of the MEMS element and any existing ASICs on the substrate. Accordingly, integrating an ASIC in the microphone package inevitably leads to an enlarged package surface area. Along with the package surface area, the manufacturing costs also increase, making microphone packages of this kind relatively expensive.

### SUMMARY

Measures are described herein which make possible a cost-effective and space-saving realization of an element package having an access channel to the membrane structure. This is achieved in that at least one further semiconductor component having at least one through hole above the MEMS element is integrated in the molding compound at a distance from the membrane structure, so that a hollow space is located between the semiconductor component and the membrane structure, and so that the access port in the molding compound opens through into the through hole of the semiconductor component and that, together with this and the hollow space between the semiconductor component and the membrane structure, forms an access channel to the membrane structure.

Departing from the side-by-side configuration of conventional pressure sensor packages, the packaging described herein is based on a stacked configuration of at least one semiconductor component over the MEMS element. A stacked configuration not only makes it possible to reduce the lateral package size, but also makes possible a realization of the access channel to the membrane structure that is reliable in terms of process, and, in fact, using standard methods of semiconductor processing, of assembly and connection technology, and molding technology, i.e., transfer molding technology.

To that end, example embodiments of the present invention provide that at least one through hole be produced in the semiconductor component already in the course of the processing of the further semiconductor component at the wafer level. Methods, such as trenching, for example, are provided for this purpose which enable the dimensions and also the position of the through holes to be predefined very precisely. Thus, very small through holes having a diameter in the μm range may be realized.

The thus prepared semiconductor component is mounted on the top side of the MEMS element at a distance from the membrane structure. For that purpose, a common bonding material from assembly and connection technology is used, which makes it possible to fashion a hollow space between the semiconductor component and the membrane structure that is connected to the through hole.

Finally, the MEMS element, together with the semiconductor component, is integrated in a molding compound in a standard molding process. In this context, an access port, which opens through into the through hole of the semiconductor component, is kept clear. In this case, the corresponding tool may be set down directly on the semiconductor component since it does not contain any fragile structures. Even the occurrence of a mold flash is not critical in this case, as long as the access port and the through hole in the semiconductor component remain free. At any rate, the sensitivity of the membrane structure is not adversely affected in the process. Since the design of the molding tools and of the molding process do not depend on the MEMS design to the extent that the above discussed conventional arrangement does, a substantially higher output is achieved in the manufacturing process.

Moreover, the component package described herein may be manufactured at low cost on multi-panel substrates, thus in a volume production. Moreover, the package design described herein makes possible a substantial decoupling of stress between the semiconductor component and the substrate. On the one hand, the distance between the semiconductor component and the substrate is relatively large. On the other hand, the semiconductor component substantially bonds only with molding compound whose thermal expansion coefficient is readily adaptable to the material of the semiconductor component. This makes it possible to largely prevent thermomechanically induced stresses in the semiconductor component and any signal drift caused by the same.

Although the semiconductor component is configured over the MEMS element, and the membrane structure protects against external influences in the manner of a cap, the lateral dimensions of the semiconductor component only need to be adapted to a limited extent to those of the MEMS element. By using a bonding layer to couple the semiconductor component and the MEMS element, lateral size differences between the semiconductor component and the MEMS element may also be readily compensated. The package design described herein makes it possible to both combine a laterally larger semiconductor component with a smaller MEMS element, as well as a smaller semiconductor component with a laterally larger MEMS element.

In general, there are different options for realizing a component package, particularly with regard to the configuration and integration of the semiconductor component.

In example embodiments, the semiconductor component is mounted on the top side of the MEMS element over a structured bonding layer that remains permanently in the package assembly. In this case, a structurable adhesive is used as bonding material that is applied either to the top side of the MEMS element or also to the mounting side of the semiconductor component and, for example, is lithographically structured in order to realize a clearance between the semiconductor component and the membrane structure. For that purpose, the membrane region is kept free of bonding material. In this arrangement, the frame region of the membrane structure must be peripherally joined to the semiconductor component in order to prevent the penetration of molding compound during the subsequent molding process.

In another especially advantageous variant, the semiconductor component is mounted on the MEMS element using a temporary adhesive layer. The temporary adhesive layer is applied either to the top side of the MEMS element or to the mounting side of the semiconductor component and, in fact, at least in the region of the membrane structure. Following the molding process during which the semiconductor component, together with the MEMS element, is integrated in the molding compound, the temporary adhesive layer is removed again, a hollow space forming between the semiconductor component and the membrane structure. Thus, in this case, the temporary adhesive layer is not only used to fix the stack in position on the MEMS element and the semiconductor component, but it also defines the hollow space and, in this respect, has a sacrificial layer function.

This arrangement is particularly suited for packages that include an MEMS element and a semiconductor component having different lateral dimensions.

Suited as material for the temporary adhesive layer is, for example, a thermoplastic-based polymer lacquer from the group of polycylic olefins that is photochemically, wet-chemically or dry structurable and features a high force of adhesion to silicon and metal. The softening point of this type of thermoplastic polymer lacquer resides within a region of 100° C. and above. Typical decomposition temperatures reside within a range of between 200° C. and 260° C. Lower decomposition temperatures are also possible. Carbon monoxide, carbon dioxide and hydrogen occur as decomposition products.

Example embodiments of the component package provide for the position of the semiconductor component within the package to be additionally stabilized with the aid of a glue seam which permanently joins the semiconductor component to the MEMS element, at least on one side.

The semiconductor component may be integrated both face-up, as well as face-down in the molding compound of the component package according to the present invention. The semiconductor component may be configured to allow the through hole to be positioned directly over the membrane structure. However, for certain applications, it may also be advantageous for the through hole of the semiconductor component to be positioned laterally above the membrane structure, for example, to protect the membrane structure from environmental influences. Example embodiments provide for a formed filter structure to be configured in the region of the through hole in the semiconductor component to prevent dirt particles from penetrating to the membrane structure. This may be a grid-type, porous, membrane-type or foil-type structure.

Although exemplary embodiments described herein relate to microphone packages, the present invention is not limited to such components, but encompasses more generally the components having MEMS elements that are equipped with a fragile membrane structure and require a media access in the housing.

Further features and aspects of example embodiments of the present invention are described in more detail below with reference to the appended Figures.

### BRIEF DESCRIPTION OF THE DRAWING

FIGS. 1a to 1f illustrate the individual method steps entailed in the production of a first microphone package 10 according to an example embodiment of the present invention with reference to sectional views of the design.

FIGS. 2a to 2c illustrate another production variant with reference to sectional views of the design.

FIG. 3 shows the sectional view of a microphone package 30 having a glue seam between the ASIC and the microphone element.

FIGS. 4a and 4b show sectional views of microphone packages 41, 42 having ASICs which are relatively small and relatively large in comparison to the microphone element.

FIG. 5 shows the sectional view of a microphone package 50 where the ASIC is mounted face-down on the microphone element.

### DETAILED DESCRIPTION

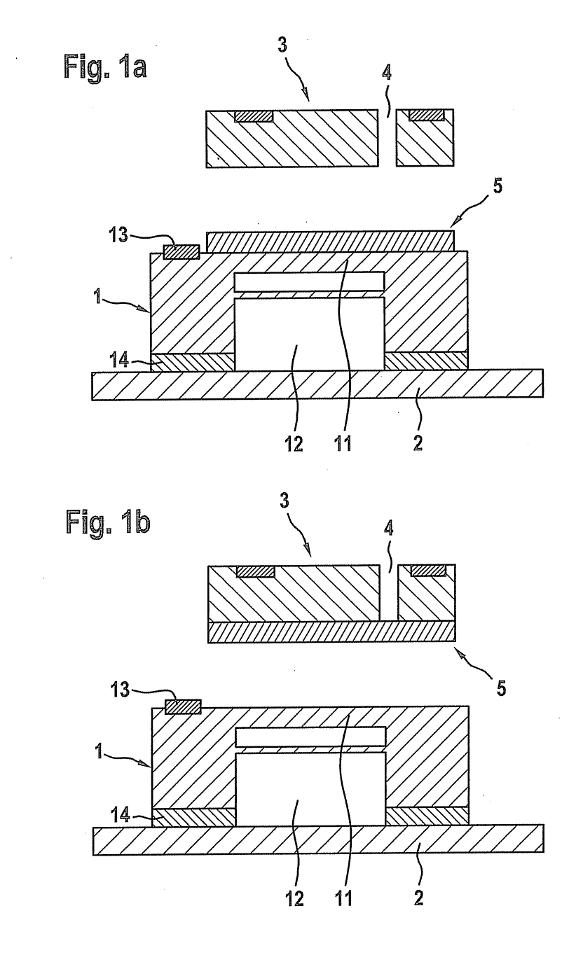

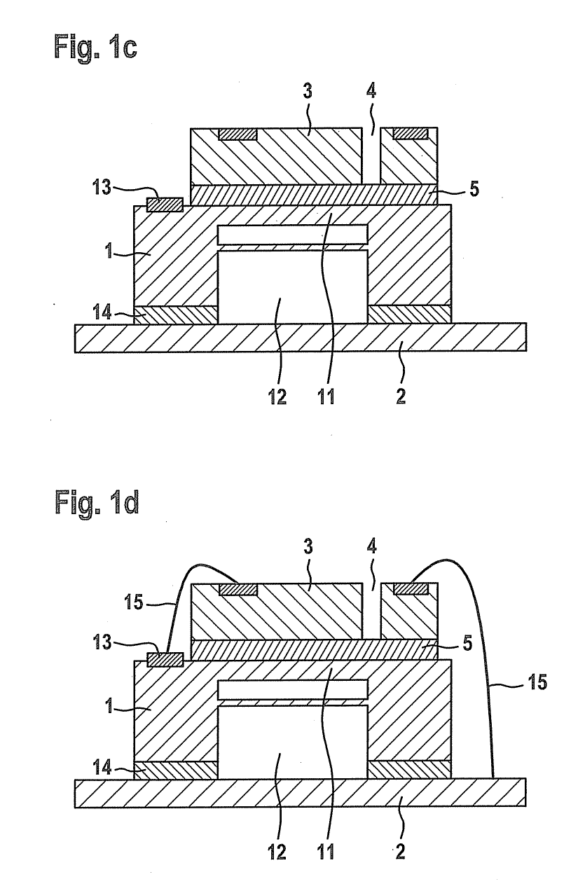

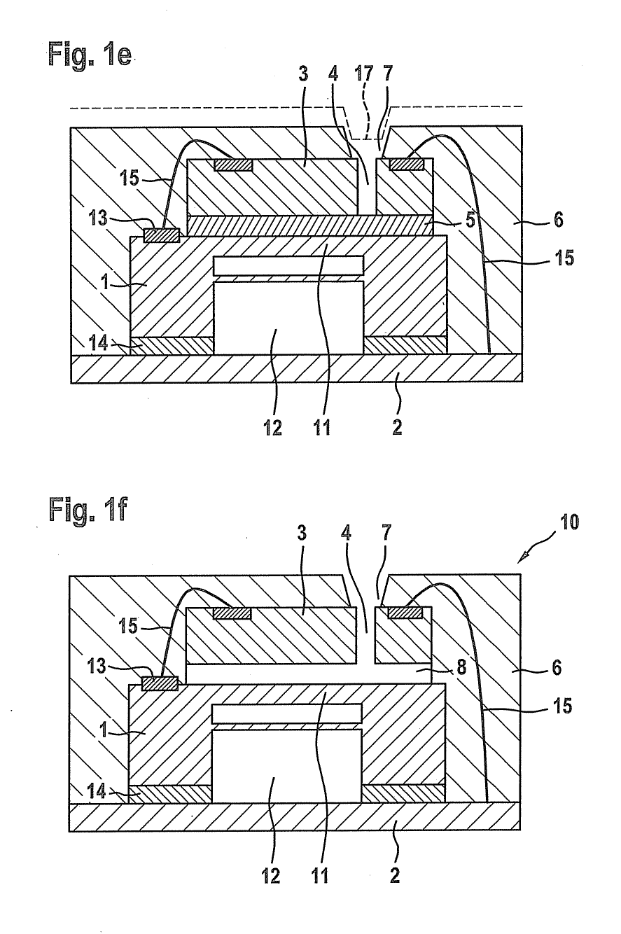

FIGS. 1a to 1b illustrate an MEMS microphone element 1 in whose top side a membrane structure 11 having signal acquisition device is configured. These may be contacted via a terminal pad 13 on the top side of microphone element 1. Membrane structure 11 spans a cavity 12 in the rear side of the element. Microphone element 1 is mounted by its rear component side on a planar substrate 2, so that the rear-side volume of microphone element 1 is bounded by cavity 12, together with substrate 2. Acoustic ports to the rear side volume may also be configured in the membrane structure. In this case, a circuit board substrate, on which microphone element 1 has been fixed in position with the aid of adhesive 14, is used as substrate 2. The circuit board substrate is advantageously a multi-panel substrate.

Illustrated above microphone element 1 in each case is an ASIC 3 having a through hole 4 that is to be configured on microphone element 1 and with clearance from membrane structure 11. In the exemplary embodiment illustrated here, ASIC 3 is to be joined via a temporary adhesive layer 5 to microphone element 1. In the case of FIG. 1a, this temporary adhesive layer 5 is applied to the top side of microphone element 1, so that adhesive layer 5 extends over the entire membrane region, not, however, over terminal pad 13. In the case of FIG. 1b, temporary adhesive layer 5 is applied over the entire surface of the mounting side of ASIC 3. In both cases, temporary adhesive layer 5 may then be applied at the wafer level, i.e., in the course of chip production, for example using spin-on deposition, and optionally structured as well.

The bond between ASIC 3 and microphone element 1 is then produced in a bonding step in which adhesive layer 5 is melted. The process parameters temperature, residence time and cohesion are regulated as a function of the material of adhesive layer 5. The result of this bonding step is illustrated in FIG. 1c.

The thus stacked components—microphone element 1 and ASIC 3—are electrically contacted amongst themselves and to circuit board substrate 2 with the aid of bonding wires 15, as is illustrated in FIG. 1d.

Together with bonding wires 15, microphone element 1 and ASIC 3 are then sheathed with molding compound 6 in a transfer molding process, as is illustrated in FIG. 1e. A plunger-type molding tool 17 is placed on the top side of ASIC 3 sealingly above through hole 4 in order to keep the same free of molding compound 6. To compensate for the tolerances between tool 17 and the ASIC surface, a special foil or even a flexible tool coating may be used. An acoustic access port 7, which opens through into through hole 4 of ASIC 3, is thereby formed in molded housing 6. A suitable plastic molding material, such as an epoxide compound filled with silicon oxide particles, for example, is used as molding compound 6.

Only after ASIC 3, together with microphone element 1, has been integrated in molded housing 6, is temporary adhesive layer 5 removed. Depending on the material of temporary adhesive layer 5, this may be accomplished chemically, thermally or also dry chemically. At any rate, between ASIC 3 and membrane structure 11, a hollow space 8 is formed in the process that is connected to through hole 4 in ASIC 3 and thus also to acoustic access port 7 in molded housing 6, and is laterally delimited exclusively by molding compound 6.

The result of the above described method is depicted in the form of microphone package 10 in FIG. 1f. Acoustic access port 7 is configured in the top side of package 10 at a lateral offset from membrane structure 11. Together with through hole 4 in ASIC 3 and hollow space 8 between ASIC 3 and membrane structure 11, it forms the acoustic access channel of microphone package 10.

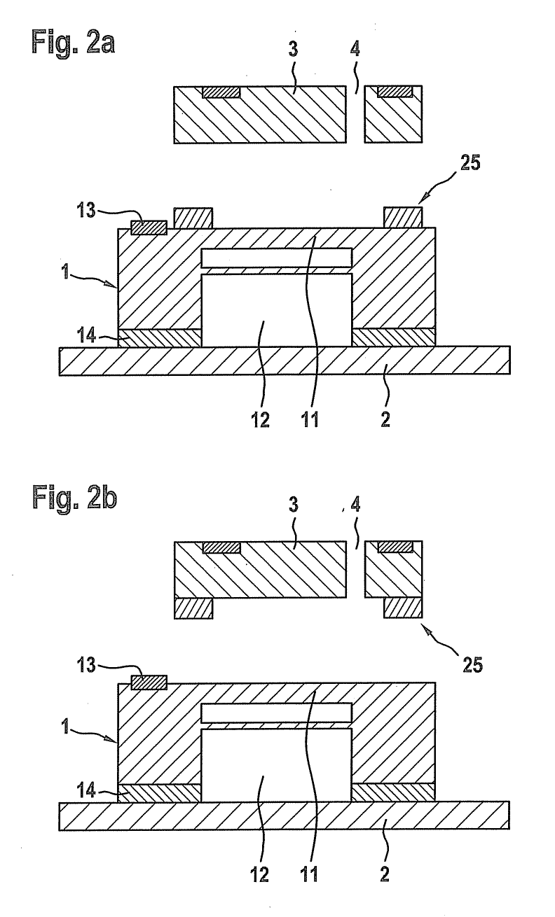

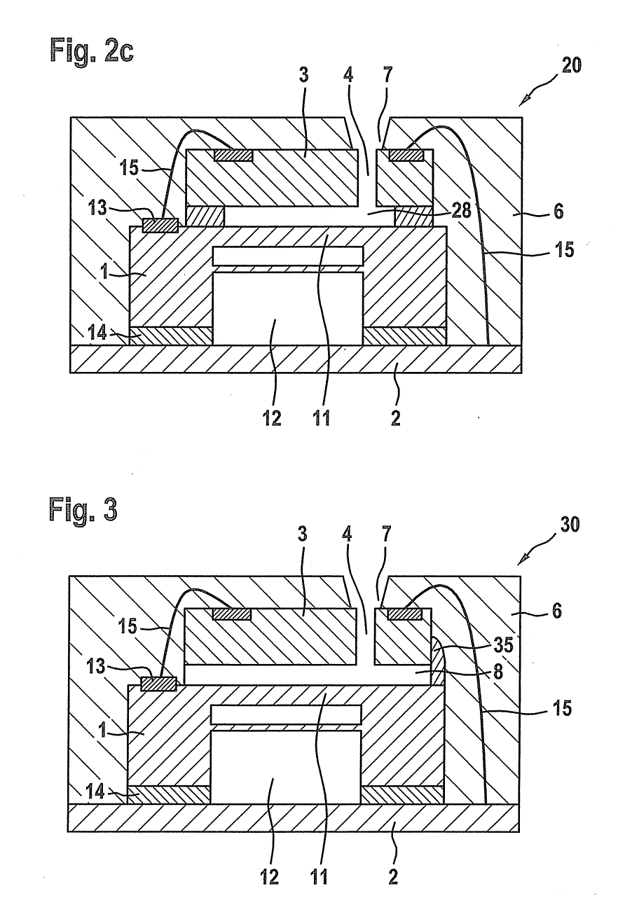

As in the case of FIGS. 1a and 1b , FIGS. 2a and 2b illustrate an MEMS microphone element 1 having a membrane structure 11 in the component top side and a terminal pad 13 on the component top side that is mounted by the rear component side on a planar substrate 2, so that cavity 12 below membrane structure 11, together with substrate 2, forms the rear-side volume of microphone element 1.

Illustrated above microphone element 1 in each case is an ASIC 3 having a through hole 4, that is to be configured on microphone element 1 and with clearance from membrane structure 1. In the exemplary embodiment illustrated here, ASIC 3 is joined to microphone element 1 via a structured adhesive layer 25 that remains permanently in microphone package 20. In the case of FIG. 2a, this adhesive layer 25 is applied to the top side of microphone element 1 and structured such that it extends merely over the frame region of membrane structure 11. In the case of FIG. 2b, adhesive layer 25 was applied to the mounting side of ASIC 3 and structured accordingly. Here as well, adhesive layer 25 may be applied in both cases already at the wafer level, i.e., in the course of chip production, and be structured using a lithographic process, for example. Not included in each case is the region of membrane structure 11, nor is/are terminal pad(s) 13. Due to this structuring of adhesive layer 25, a hollow space 28 is formed between ASIC 3 and membrane structure 11 that is laterally terminated by adhesive layer 25.

Comparably to the first exemplary embodiment described above, the thus stacked components—microphone element 1 and ASIC 3—are electrically contacted amongst themselves and to circuit board substrate 2 via bonding wires 15. In the then following molding process, microphone element 1 and ASIC 3, together with bonding wires 15, are embedded in molding compound 6. In the process, through hole 4 in ASIC 3 is covered with the aid of a plunger type molding tool, so that an acoustic access port 7 is formed in the top side of molded housing 6.

FIG. 2c shows the thus fabricated microphone package 20. Here as well, acoustic access port 7 is configured in the top side of package 20 at a lateral offset from membrane structure 11, and, together with through hole 4 in ASIC 3 and hollow space 28 between ASIC 3 and membrane structure 11, forms the acoustic access channel of microphone package 20. In contrast to microphone package 10 (FIG. 1f), hollow space 28 is laterally delimited by structured adhesive layer 25 which remains permanently in the structure of microphone package 20.

FIG. 3 illustrates a microphone package 30 whose design corresponds substantially to that of microphone package 10 of FIG. 1f. To enhance ruggedness and reliability, this design was merely supplemented by additional glue seams 35 that join at least one of the sides of ASIC 3 to the surface of microphone element 1 and, in this manner, mechanically stabilize the chip stack.

By varying the thickness of the temporary adhesive layer between the ASIC and the microphone element and the parameters temperature, residence time and holding force of the bonding step, it is possible, on the one hand, to influence the bonding depth, i.e., how far the ASIC sinks into the adhesive layer, and, on the other hand, the form of the menisci at the ASIC edges. The higher the bonding temperature is, the greater the degree of softening of the temporary adhesive layer, and the further the ASIC sinks into the adhesive layer, given the same cohesion. This is advantageous during the subsequent transfer molding process since the ASIC embedded in this manner in the adhesive layer produces less flow resistance than does a mounted chip at the steep side thereof. For this reason, it is also preferred that substantially thinned ASICs be integrated in a microphone package.

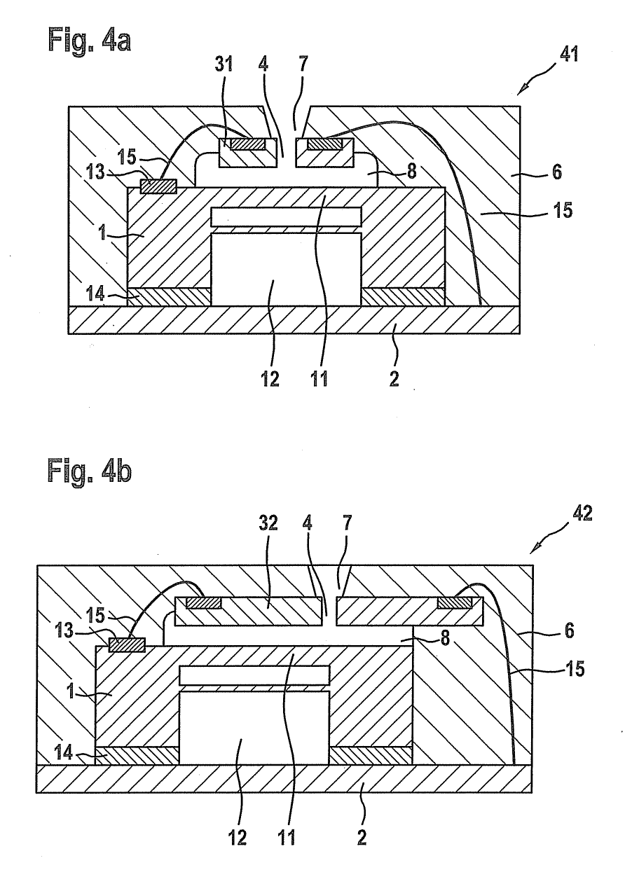

FIGS. 4a and 4b depict two microphone packages 41 and 42 where the lateral dimensions of microphone element 1 and ASIC 31, respectively 32 deviate significantly from one another. In both cases, these size differences are compensated by suitably structuring the temporary adhesive layer.

In the case of microphone package 41, ASIC 31 is not only distinctly smaller than microphone element 1, but also than the lateral dimensions of membrane structure 11. Nevertheless, the entire membrane surface is covered by the temporary adhesive layer in order to protect this region during the molding process and keep it free of the molding compound. From the shape of hollow space 8 formed following the molding process by removing the temporary adhesive layer, it is inferable that ASIC 31 has sunk during the bonding process into the temporary adhesive layer to approximately 70% of its depth. In the case of microphone package 42, ASIC 32 projects out laterally over microphone element 1. ASIC 32 is applied to microphone element 1 using a temporary adhesive layer into which it sinks during the bonding process to approximately 70% of its depth.

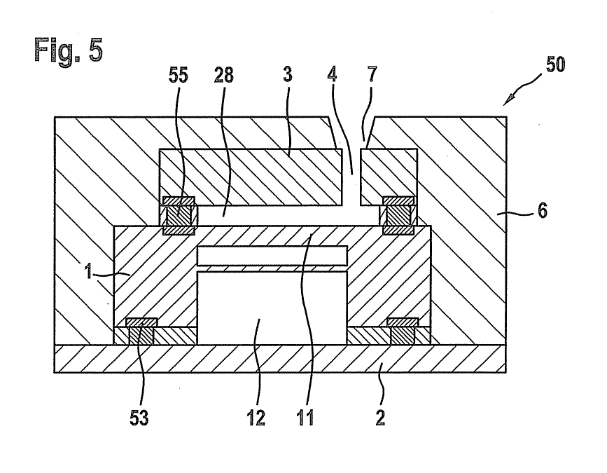

FIG. 5 shows another example embodiment 50 of the microphone package having an MEMS microphone element 1 that is mounted by the rear component side on a planar substrate 2, so that cavity 12 below membrane structure 11, together with substrate 2, forms the rear-side volume of microphone element 1. In the exemplary embodiment illustrated here, microphone element 1 is not contacted via bonding wires, rather via connections 53 in the rear side of the component. Moreover, microphone package 50 includes an ASIC 3 having a through hole 4 that is configured here using flip-chip technology, thus face down, on microphone element 1 and at a distance to membrane structure 11. In the exemplary embodiment illustrated here, ASIC 3 is joined via a structured adhesive layer 25 to microphone element 1 that remains permanently in microphone package 50 and extends merely over the frame region of membrane structure 11. Due to this structuring of adhesive layer 25, a hollow space 28, which is laterally terminated by adhesive layer 25, forms between ASIC 3 and membrane structure 11. Electrical connection 55 between ASIC 3 and microphone element 1 is then established here via stud bumps, copper-pillar solder globules. Microphone element 1 and ASIC 3 are embedded in the plastic molding material of molded housing 6. An acoustic access port 7, which opens through into through hole 4 in ASIC 3, is formed in the top side of molded housing 6. This through hole 4 is connected to hollow space 28 between ASIC 3 and membrane structure 11, so that microphone package 50 is equipped with a through-going acoustic access channel from the top side of the package to membrane structure 11.

Since, in the case of microphone package 50, components 1 and 3 are not contacted via bonding wires, and the rear side of ASIC 3 is typically insensitive to external influences, molded housing 6 may also terminate flush with the rear side of ASIC 3. In this case, together with through hole 4, the entire component rear side of ASIC 3 is kept free of molding compound 6 during the molding process. Accordingly, this obviates the need for using a special plunger-type molding tool to keep through hole 4 clear.

To maintain the lowest possible acoustic resistance, exemplary embodiments provide for at least 100 μm to be selected as a distance between ASIC 3 and MEMS component 1. A distance of this kind may be observed in the case of all of the exemplary embodiments described above.

What is claimed is:

1. A component, comprising:
at least one MEMS element;
at least one membrane structure arranged in a top side of the MEMS element;
a substrate, a rear side of the MEMS element mounted on the substrate;
a molding compound, the MEMS element at least partially embedded in the molding compound; and
at least one access port formed in the molding compound;
wherein at least one further semiconductor component having at least one through hole above the first MEMS element is integrated in the molding compound at a distance from the membrane structure, a hollow space being located between the further semiconductor component and the membrane structure, and the access port in the molding compound opening through into the through hole of the further semiconductor component, an access channel to the membrane structure being formed by the access port, the through hole, and the hollow space.

2. The component according to claim 1, wherein the further semiconductor component is joined via a structured adhesive layer to the MEMS element at least in a frame region of the membrane structure.

3. The component according to claim 1, wherein the further semiconductor component is joined at least on one side via a glue seam to the MEMS element.

4. The component according to claim 1, wherein the further semiconductor component is integrated face-up or face-down in the molding compound over the MEMS element.

5. The component according to claim 1, wherein the further semiconductor component is configured to allow the through hole to be positioned directly or laterally above the membrane structure.

6. The component according to claim 1, wherein a formed filter structure is arranged in a region of the access channel or in a region of the through hole of the further semiconductor component.

7. The component according to claim 1, wherein a distance between the MEMS element and the further semiconductor component is at least 100 μm.

8. A microphone package, comprising:
a MEMS microphone element;
at least one membrane structure arranged in a top side of the microphone element and spanning a cavity in a rear side;
a substrate, the microphone element mounted by a rear side thereof on the substrate, a rear side volume of the microphone element being bounded by the cavity together with the substrate;
a molding compound, the microphone element at least partially embedded in the molding compound; and
at least one acoustic access port formed in the molding compound;
wherein at least one further semiconductor component having at least one through hole above the microphone element is integrated in the molding compound at a distance from the membrane structure, a hollow space being located between the semiconductor component and the membrane structure, the acoustic access port in the molding compound opening through into the through hole of the further semiconductor component, an access channel to the membrane structure being formed by the access port, the through hole, and the hollow space.

9. A method for manufacturing a component, comprising:
mounting a first MEMS element having at least one membrane structure by a rear side thereof on a substrate;
mounting at least one further semiconductor component having at least one through hole on the first MEMS element at a distance from the membrane structure by a bonding material that makes it possible to fashion a hollow space between the further semiconductor component and the membrane structure that is connected to the through hole;
electrically interconnecting the first MEMS element and the further semiconductor component, or electrically connecting the first MEMS element and the further semiconductor component to the substrate; and
integrating the first MEMS element and the further semiconductor component, together with the electrical connections, in a molding compound in a molding process, an access port, which opens through into the through hole of the further semiconductor component, being kept free of molding compound.

10. The method according to claim 9, wherein, as a bonding material between the further semiconductor component and the first MEMS element, a structurable adhesive is used that is applied to a top side of the first MEMS element or to a mounting side of the further semiconductor component and is structured such that a membrane region is freed of adhesive, and at least a frame region of the membrane structure is peripherally provided with adhesive.

11. The method according to claim 9, wherein, as a bonding material between the further semiconductor component and the first MEMS element, a temporary adhesive layer is used that is applied at least in a region of the membrane structure to a top side of the first MEMS element or to a mounting side of the further semiconductor component, and is removed again following the molding process.

12. The method according to claim 9, wherein, during the molding process, a plunger-shaped molding tool is placed over the through hole of the further semiconductor component to keep the through hole free of molding compound.

13. The method according to claim 9, wherein a compensation foil and/or molding tools having a flexible coating are used during the molding process.
